(19) United States
(12) Patent Application Publication
(10) Pub. No.: US 2012/0052204 A1
(43) Pub. Date: Mar. 1, 2012

(54) WORKPIECE WETTING AND CLEANING

(75) Inventors: Bryan Puch, Kalispell, MT (US); Kyle M. Hanson, Kalispell, MT (US); Marvin Bernt, Kalispell, MT (US); Paul R. McHugh, Kalispell, MT (US); Gregory J. Wilson, Kalispell, MT (US)

(73) Assignee: Applied Materials, Inc., Kalispell, MT (US)

(21) Appl. No.: 12/873,002

(22) Filed: Aug. 31, 2010

(51) Int. Cl. C23C 16/56

(52) U.S. Cl. 427/255.23

(57) ABSTRACT

In a workpiece processor, a head is moveable onto a bowl to form a process chamber. A workpiece can be cleaned in the processor by immersing the workpiece into a liquid bath in the bowl and then boiling the liquid. Vacuum may be applied to the chamber to reduce the pressure within the chamber, thereby reducing the boiling temperature of the liquid and allowing processing at lower temperatures. In a separate method for prewetting a workpiece, a humid gas is provided into the process chamber and condenses on the workpiece. In another separate method for wetting a workpiece, liquid water is provided into the bowl, with the workpiece above the liquid water. Water vapor is created in the process chamber by applying vacuum to the process chamber. The vapor wets the workpiece. The workpiece is then further wetted by submerging the workpiece into the liquid water.

### BACKGROUND

In manufacturing semiconductor devices, and similar micro-scale devices, it is often necessary to pre-wet a wafer or other substrate. Pre-wetting can be achieved in basic forms by simply immersing the substrate into a bath of liquid, typically de-ionized (DI) water, or by spraying liquid onto the substrate. However, as substrates are patterned with increasingly smaller features, such as trenches and vias, existing pre-wetting techniques become less reliable. Surface tension and other effects can prevent the liquid from contacting all surfaces of the substrate, especially recessed feature surfaces. Larger features having high aspect ratios may also not be consistently fully wetted by immersion or spraying. This can result in defects during follow on manufacturing steps, such as plating steps, where voids and miss-filled features may occur at localized microscopic dry areas of the substrate.

Various approaches for improved pre-wetting have been proposed, including use of solvents, surfactants, or other chemicals. These approaches have met with varying degrees of success and disadvantages remain. For example, the techniques using these chemicals do not necessarily eliminate all localized microscopic dry areas. These techniques also generally requires additional manufacturing steps and equipment, in addition to the complications and costs of obtaining and using the chemicals. Use of such chemicals may also affect later processing steps and create chemical compatibility issues.

Particles and other contaminants can cause defects in micro-scale devices. It is therefore essential to effectively clean substrates during various steps of the manufacturing process. However, the cleaning must of course be performed without damaging the often delicate features of the substrates. Providing effective cleaning apparatus and methods consequently presents engineering challenges. Accordingly, improved techniques are needed.

### BRIEF DESCRIPTION OF THE DRAWINGS

In the drawings, the same element number indicates the same element, in each of the views.

FIG. 1 is a side view of a processor in a head-up load/unload position.

FIG. 2 is a side view of the processor shown in FIG. 1 in a head-down position and with the head picking up a workpiece.

FIG. 3 is a section view of the processor shown in FIGS. 1 and 2, with the processor now in a process position.

FIG. 4 is a perspective view of the processor in the process position.

### DETAILED DESCRIPTION

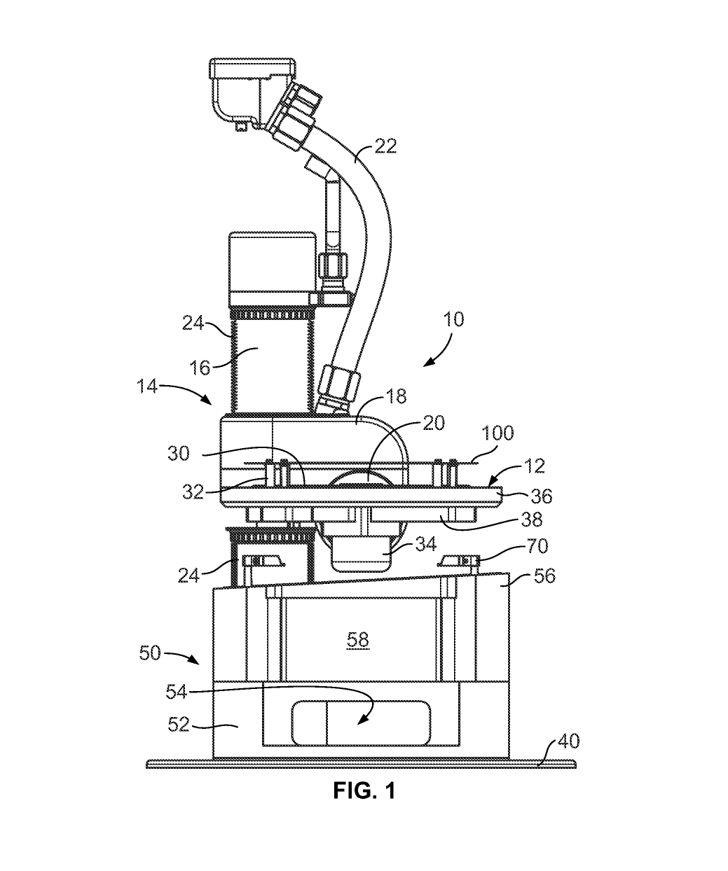

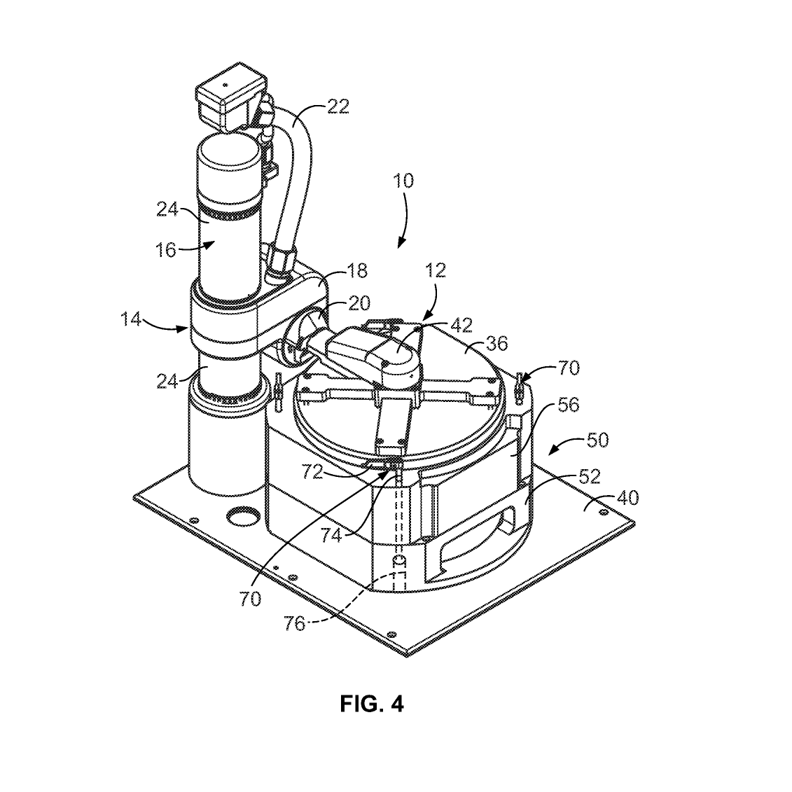

Turning now in detail to the drawings, as shown in FIGS. 1, 2 and 4, a processor 10 has a head 12 that may be supported on a head arm 42 attached to a rotator 20 of a lift/rotate mechanism 14. The rotator 20 is shown in FIG. 4 attached to a lift arm 18 which may be lifted and lowered by a lifter 16 of the lift/rotate mechanism 14. Bellows 24 may be provided around the lifter 16 above and below the lift arm 18. Power and control cables 22 may extend up and connect into a processing system, as described for example, in U.S. Patent Application Publication No. US 2005/0063798, incorporated herein by reference.

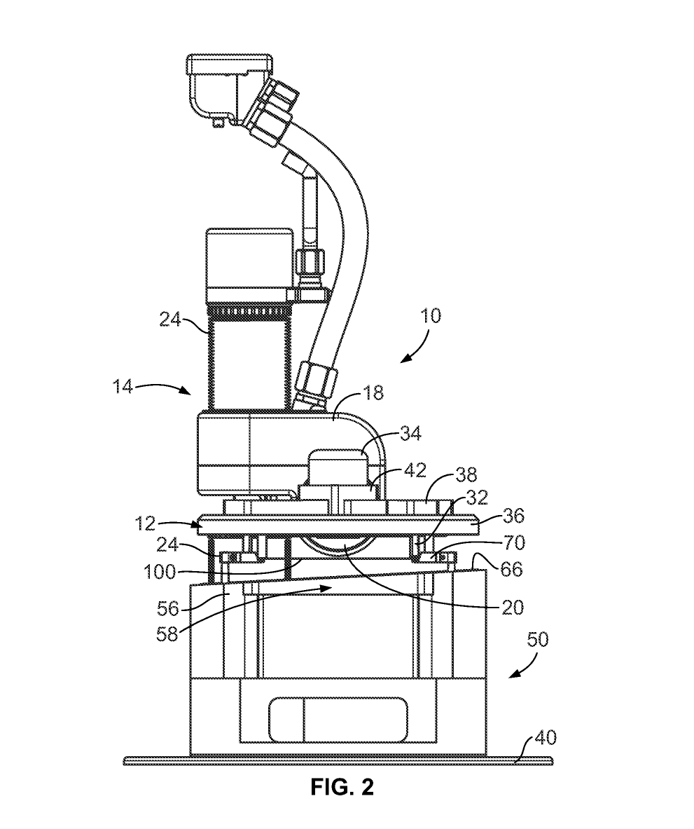

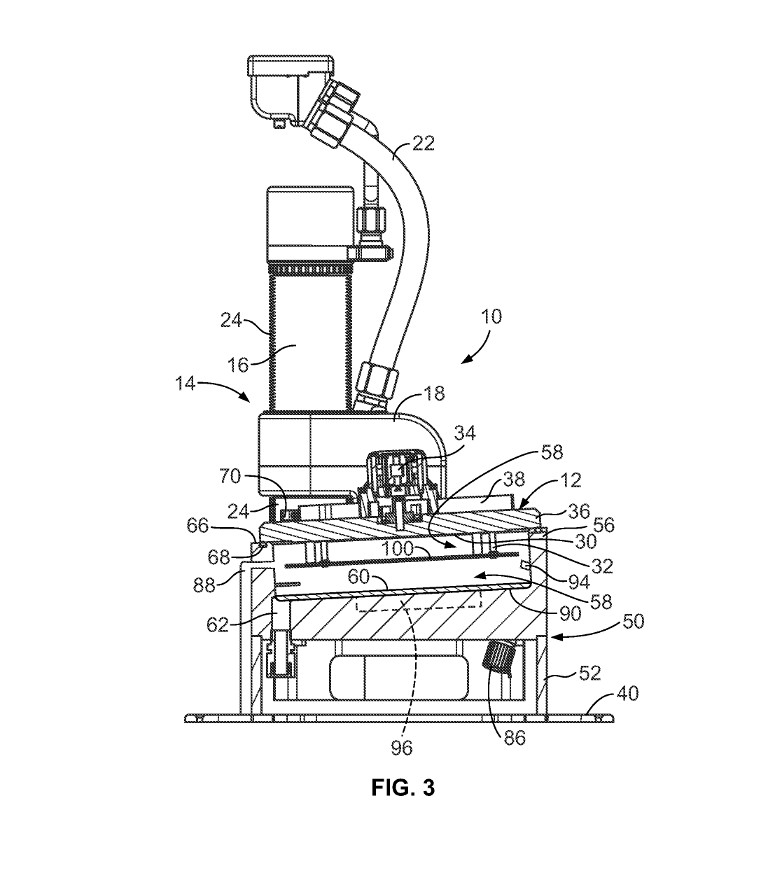

Referring to FIGS. 1 and 2, a rotor 30 with workpiece holders 32 may be provided on the head 12, with the rotor 30 rotatable via a rotor motor 34 attached to a head plate 36. Alternatively, if no rotor is used, the workpiece holders 32 may be attached to the head plate 36. As shown in FIGS. 3 and 4, a bowl assembly 50 is supported on a base plate or deck 40 of a processing system, which may have multiple processors 10. The bowl assembly 50 may have a bowl 56 on top of a pedestal 52. The pedestal 52, if used, can have access openings 54 to allow access to bowl components, and to facilitate plumbing and electrical connections to the bowl 56.

As shown in FIG. 3, with the head 12 on top of the bowl 56, an enclosed chamber 58 is formed within the processor 10. The floor 60 of the bowl 56 may be on an incline, with a drain 62 at the lower side of the bowl 56. The top surface or rim 66 of the bowl 56 may also be on an incline, and parallel to the floor 60 of the bowl 56. A seal element 68, such as an o-ring, is provided on or in the rim 66. A liquid fill inlet line 86 leads into the bowl 56 from a liquid supply source. A vacuum line 88 runs from the bowl 56 to a vacuum source. Referring still to FIG. 3, one or more sonic elements 96, such as a megasonic transducer 96, one or more heaters 90, and one or more spray nozzles 94, may also be provided in the bowl 56.

Referring once again to FIG. 4, levers 70 may be provided on the bowl to provide a temporary support for holding a workpiece 100. Each lever 70 may include a lever arm 72 attached to a shaft 74 turned by a motor 76. With the head lifted up and levers 70 pivoted inwardly, the levers 70 provide a temporary support where a system robot can drop off a workpiece. After the workpiece is picked up by the head, the levers 70 are pivoted outwardly to avoid interfering with movement of the head down onto the bowl.

The processor 10 can perform several different types of processing methods. In these methods, a workpiece or wafer 100 is initially loaded into the processor 10. As shown in FIG. 1, the lift/rotate mechanism 16 rotates the head 12 into a face-up position. A wafer 100 is then placed into the head and grasped at the edges by the wafer holders 32. The lift/rotate mechanism 16 then lifts the head 12 and rotates the head 12 into a face-down position, as shown in FIG. 2. The lift/rotate mechanism 16 then lowers the head 12 down onto the bowl 56. If the bowl 56 has an inclined top rim 66, the lift/rotate mechanism 14 also rotates the head so that the head plate 36 is parallel to the top rim 66.

In some automated processing systems, the system robot delivers the workpiece 100 to the processor 10 in a face-up position (i.e., the patterned side of the workpiece is facing up). In this type of system, if the workpiece 100 is loaded into the head 12 face up, as shown in FIG. 1, once the head rotates over, to the position shown in FIG. 2, the workpiece 100 is face down. In processes, results may be improved with the workpiece processed face-up, due to buoyancy forces on bubbles and contaminants, and other factors. The levers 70 allow for face up processing. Specifically, with head 12 lifted up from the bowl, the levers 70 are pivoted inwardly. The system robot then places a workpiece 100 down onto the levers, with the workpiece face up. The head 12 then moves down and the workpiece holders 32 move radially inwardly to grip the edges of the workpiece. The head then lifts up slightly to lift the workpiece up off of the levers. The levers 70 then pivot outwardly and out of the way to allow the head to move down into contact with the bowl 56.

A pressure-tight chamber 58 may be formed within the processor via the head plate 36 pressing onto the seal element 68 on the top rim 66, as shown in FIG. 3. However, not all of the methods that the processor 10 may perform necessarily require a sealed pressure-tight chamber 58.

In summary, a wafer processor includes a process chamber having a bowl for holding liquid and an access opening for moving a workpiece into and out of the process chamber; a cover moveable to engage and seal against the bowl during processing and removable from the bowl for moving a workpiece into and out of the process chamber; a vacuum source connecting into the process chamber; a liquid source connecting into the bowl; a liquid drain connecting into the bowl; and a heater for heating liquid from the liquid source. The processor may also have one or more of: a head supported on a lift/rotate mechanism, and with the head including a rotor adapted to rotate a workpiece within the process chamber; workpiece holders on the head moveable to lift and lower a workpiece vertically in the process chamber; the cover including a head supported on head arm attached to a rotator of a lift/rotate mechanism, and with the bowl having a non-horizontal top rim; the bowl having a non-horizontal floor substantially parallel to the top rim; and the heater in the bowl below the floor of the bowl.

In a method for cleaning a workpiece, and with the workpiece in processing position as shown in FIG. 3, a liquid is provided into the bowl 56 via the inlet 86 while the drain line 62 is closed. The workpiece is immersed into the liquid. This can be achieved by holding the workpiece in a fixed position and sufficiently raising the level of liquid in the bowl, or by lowering the workpiece 100 into the liquid bath held in the bowl 56. The workpiece may be lowered into the bath of liquid in the bowl by lowering the head 12, or via use of extending or telescoping wafer holders 32 that can move the workpiece vertically. With the wafer immersed in the liquid, the liquid is brought to boiling. Alternatively, the liquid may be boiling before immersing the workpiece in the liquid. The heater 90 or multiple heaters may be used to boil the liquid. The liquid may also be preheated to boiling or near boiling before the liquid is provided into the bowl 56.

Typically the workpiece is oriented with the patterned or front surface of the workpiece microscopic features facing up, towards the head. The workpiece remains in the boiling liquid for pre-determined time interval. During this interval, the chamber 58 may or may not be sealed. The chamber may be partially or fully filled with liquid. The boiling liquid provides agitation via the creation of vapor bubbles. The agitation removes air bubbles from the micro-scale features on the workpiece, and helps to fully wet the workpiece, including surface areas in high-aspect ratio features of the workpiece. The agitation also helps to remove particles. Vapor bubbles can be formed deep within high aspect ratio features, helping to clean and wet these features. The agitation from boiling may be gentler than alternative mechanical cleaning techniques, such as spraying and sonic cleaning, to help avoid damage to fragile features on the workpiece.

During the boiling step, the pressure in the chamber 58 may be reduced to lower the boiling temperature of the liquid. The pressure may be reduced by sealing the chamber 58 via contacting the head plate 36 against the seal element 68, and applying vacuum to the vacuum line 88. Reducing the pressure in the chamber 58 allows the liquid to boil at a lower temperature. This can help avoid damage and degradation of the workpiece features and materials. On the other hand, liquid surface tension decreases with increasing temperature, so that higher temperatures may be advantageous for wetting the workpiece. The desired temperature of the boiling liquid may be adjusted, within limits, by adjusting the pressure in the chamber. With workpieces not susceptible to damage at typical liquid boiling temperatures, the boiling step may be performed with the chamber 58 at ambient pressure, with no chamber sealing or vacuum needed.

The liquid may be DI water. The water may be de-gassed in advance. Where DI water is used, a surfactant, isopropyl alcohol, or another cleaning chemical, may be added. Referring to FIG. 3, in processors 10 that include a rotor 30 in the head 12, the rotor 30 may rotate the workpiece 100 during the boiling step. Sonic energy, such as megasonics, may also optionally be provided to the workpiece through the liquid via one or more sonic elements 96. After completion of the boiling step, the liquid may be removed via the drain line 62, and the workpiece 100 is removed from the processor 10 for subsequent processing steps. Before it is removed, the workpiece may optionally be sprayed with liquid from spray nozzles 94 in the chamber 58. The sprayed liquid may be the same as the boiling liquid, or a second different liquid may be sprayed onto the workpiece.

In summary, a method for cleaning a workpiece having microscopic device features includes introducing a liquid into the chamber; immersing a workpiece into the liquid; and boiling the liquid with the workpiece immersed in the boiling liquid, with the boiling creating bubbles on the surface of the workpiece and within microscopic features on the workpiece. This method may further include one or more of the steps of: a) sealing the chamber and reducing the pressure within the chamber, to reduce the boiling temperature of the liquid; removing the workpiece from the liquid and spraying the workpiece with a second liquid in the chamber; preheating the liquid before introducing the liquid into the chamber; rotating the workpiece in the boiling liquid; introducing sonic energy into the liquid; and degassing the liquid before introducing the liquid into the chamber. The liquid may comprise de-ionized water, and one or more of a surfactant, isopropyl alcohol, or another cleaning chemical. The liquid may partially or completely fill the chamber.

The processor 10 may also perform methods for prewetting a workpiece. In these methods, with the workpiece in the processing position as shown in FIG. 3, a humid gas is introduced into the process chamber. The humid gas is at a temperature above the temperature of the workpiece, so that humid gas condenses on the workpiece. The condensation forms liquid on the surfaces of the workpiece, including within high aspect ratio features, which can be difficult to wet.

This condensation prewetting method can be carried out with the chamber 58 at ambient pressure. Alternatively, the chamber may be sealed and the pressure may be reduced, as described above. With the chamber 58 at a partial vacuum condition, steam or other vapor, such as isopropyl alcohol vapor, is provided into the chamber 58, with the vapor condensing on the workpiece. This condensation prewetting can reduce or prevent formation of air bubbles in the features of the workpiece, when the workpiece is coated, sprayed, or immersed in liquid in subsequent processing steps. The humid gas may be heated and/or the workpiece cooled in advance, to increase condensation.

With vacuum applied to the chamber 58, gas within the chamber is drawn out of the chamber and from substantially all features on the workpiece. Then, when water vapor is created in or introduced into the chamber, the features will necessarily contain water gas molecules rather than air molecules. When the humid gas then condenses, the liquid will be more likely to wet inside the features. However, even in the event that gas bubbles become trapped in a feature during condensation or submersion, the gas bubbles will be bubbles of water vapor. Then, when atmospheric pressure is reintroduced to the chamber the bubbles will compress and wet the features.

In an alternative condensation prewetting method, DI water is first provided into the bowl 56, with the DI water forming a bath of liquid in the chamber, and the workpiece above the bath of liquid. The pressure in the chamber is then reduced to partial vacuum. This tends to pull out gas (typically air) that may be trapped in the features of the workpiece. The condensation prewetting is then performed as described above.

The processor 10 may also be used for vapor prewetting methods. In these methods, with the workpiece in the processing position as shown in FIG. 3, vacuum may be applied via the vacuum line over an initial time interval to remove ambient air or gas from the process chamber. Liquid DI water is provided into the bowl 56, with the workpiece above the liquid water. Water vapor is then generated in the process chamber by reducing the pressure within the process chamber. The pressure within the process chamber may be reduced until the liquid water is near boiling, for example, within 1° C. to 10° C. of boiling. The process chamber may then have a substantially homogenous water vapor environment. The water may optionally be heated via the heater 90. The water vapor prewets the workpiece. The workpiece is then submerged into the liquid water, completing the wetting process. The workpiece may then be removed from the liquid water and the pressure within the process chamber increased until at least some of the water vapor in the chamber condenses into liquid water on the workpiece.

In an alternative vapor prewetting method, vacuum is applied to the chamber 58, reducing the pressure within the chamber to below ambient pressure, typically to a pressure below 400, 300, 200, or 100 Torr. The pressure in the chamber may be pumped down to 50, 20 or 10 Torr. These pressure ranges may be used in the methods described above as well. Liquid, such as DI water is introduced into the bowl with the liquid level rising sufficiently to immerse the workpiece. The pressure in the chamber is then increased, for example, back to ambient or near ambient pressure, with the workpiece immersed. This may be achieved by partially or fully releasing the vacuum and allowing gas or air to flow into the chamber. Vacuum is then applied to again reduce the pressure in the chamber, as described above, to initiate a second low pressure cycle, while the workpiece remains immersed in the liquid. Additional cycles may then also be performed, with two, three, four, five or up to 10 or more cycles performed. Cycling the pressure in the chamber with the workpiece immersed helps to ensure that gas does not re-enter the features on the workpiece. Cycling the pressure can help in wetting the workpiece as it causes trapped gas bubbles to expand and contract, which helps dissolve or dislodge the bubbles

One or more processors 10 may be provided in an automated processing system. For example a processor 10 may be included in the system described in US Patent Application Publication No. 2005/0063798. In this system, one or more computer controlled robots load and unload workpieces into and out of the processor 10, and optionally into and out of other types of processors that may be included in the system. The processor 10 may also be computer controlled.

The processor 10 may also be used to dry a wafer or workpiece 100. For example, after an initial processing step where the wafer 100 is exposed to a first chemistry, the wafer 100 may be rinsed and placed into the processor 10, or the wafer 100 may optionally be rinsed in the processor 10 via a DI water spray from nozzles 94. The pressure in the chamber 58 is then reduced below ambient pressure, and the wafer 100 is wetted using the condensation or immersion methods described above. These methods help to fully wet all surfaces on the wafer 100, which correspondingly also helps to remove any droplets of the first chemistry remaining in the features. The wafer 100 can then be dried in a final step within the processor 10 by removing substantially liquid and vapor from the chamber, and reducing the pressure in the chamber. Liquid droplets remaining on the wafer 10 then boil off into vapor and are evacuated from the chamber, drying the wafer. The wafer 100 can then be further processed via a second chemistry. Accordingly, this drying method may be used for applications where cross contamination of different chemistries must be avoided, or where it is important not to leave any chemistries within features of the wafer. During the step where pressure in the chamber is increased back up towards or to ambient pressure, the chamber may be back filled partially or entirely with an inert gas, such as nitrogen, rather ambient air. The pressure cycling with inert gas back filling may be repeated as necessary to ensure that substantially no liquid remains on the wafer.

The processor 10 may also be used for thermal processes where an inert or controlled environment is needed. In thermal processes, the heaters 90 heat the wafer 100 within the chamber 58. During the thermal processes, the wafer 100 may be immersed in liquid, or supported above a liquid in the chamber 58, or the wafer 100 and the chamber 58 may be dry with no liquid present. The workpiece 100 may consequently be thermally processed, at temperatures up to 60, 80, 100 or 120° C., with the workpiece also in a controlled environment.

Thus, novel apparatus and methods have been shown and described. Various changes and substitutions can of course be made without departing from the spirit and scope of the invention. The invention, therefore, should not be limited, except by the following claims, and their equivalents.

1. A method for wetting a workpiece having microscopic device features, comprising:
introducing a humid gas into a process chamber, with the humid gas at a temperature above the temperature of the workpiece, and with humid gas condensing on the workpiece and wetting the workpiece surface without trapping air bubbles in features on the workpiece.

2. The method of claim 1 further comprising sealing the process chamber and reducing the pressure with the process chamber.

3. The method of claim 2 with the humid gas comprising water or isopropyl alcohol.

4. The method of claim 2 further comprising heating the humid gas, or cooling the workpiece, or both.

5. The method of claim 2 further including partially filling the process chamber with de-ionized water and then reducing the pressure within the process chamber.

6. A method for wetting a workpiece, comprising:
placing a workpiece into a process chamber;
introducing liquid water into the process chamber, with the workpiece above the liquid water;
generating water vapor in the process chamber by reducing the pressure within the process chamber;
submerging the workpiece into the liquid water.

7. The method of claim 6 further comprising reducing the pressure within the process chamber until the liquid water is within 10° C. of boiling.

8. The method of claim 6 further comprising sealing the process chamber and evacuating the process chamber over an initial time interval to remove ambient air or gas from the process chamber.

9. The method of claim 8 wherein the evacuating continues until the process chamber has a substantially homogenous liquid vapor environment.

10. The method of claim 6 further comprising removing the workpiece from the liquid water and increasing the pressure within the process chamber until at least some of the water vapor in the chamber condenses into liquid water.

11. The method of claim 6 further comprising heating the liquid water.

12. A method for wetting a workpiece, comprising:
A) moving a workpiece into a process chamber;
B) reducing the pressure in the process chamber to below ambient atmospheric pressure by applying vacuum to the process chamber;
C) providing a liquid into the process chamber at least until the workpiece is immersed in the liquid;
D) increasing the pressure in the process chamber, with the workpiece remaining immersed in the liquid;
E) repeating step B;
F) repeating step D; and
G) removing the workpiece from the chamber.

13. The method of claim 12 further comprising draining the liquid out of the chamber before removing the workpiece from the chamber.

14. The method of claim 12 further comprising repeating steps E and F from 2-10 times.

15. The method of claim 12 wherein the workpiece comprises a semiconductor material wafer having features with an aspect ratio greater that 3:1.

16. The method of claim 12 with the liquid comprising DI water and/or isopropyl alcohol.

17. The method of claim 12 further comprising heating liquid in the chamber.
